(19) United States
(12) Patent Application Publication
(10) Pub. No.: US 2014/0102522 A1
(43) Pub. Date: Apr. 17, 2014

(54) A-SI:H ABSORBER LAYER FOR A-SI SINGLE- AND MULTIJUNCTION THIN FILM SILICON SOLAR CELL

(71) Applicants: Marian Fecioru-Morariu, Chur (CH); Bogdan Mereu, Chur (CH)

(72) Inventors: Marian Fecioru-Morariu, Chur (CH); Bogdan Mereu, Chur (CH)

(73) Assignee: TEL SOLAR AG, Trubbach (CH)

(21) Appl. No.: 13/885,439

(22) PCT Filed: Nov. 14, 2011
(86) PCT No.: PCT/EP11/70082

§ 371 Date: Nov. 7, 2013

Related U.S. Application Data
(60) Provisional application No. 61/414,024, filed on Nov. 16, 2010.

(51) Int. Cl. H01L 31/075; H01L 31/076; H01L 31/18

(52) U.S. Cl. CPC H01L 31/075; H01L 31/1804; H01L 31/076
USPC 136/255; 438/87; 438/74

(57) ABSTRACT

The invention relates to a method for manufacturing a thin film solar cell, comprising the sequential steps of a) depositing a positively doped Si layer (3), b1) depositing a first intrinsic a-Si:H layer (21) at a first deposition rate, b2) depositing a second intrinsic a-Si:H layer (22) at a second deposition rate, and c) depositing a negatively doped Si layer (5), whereby the second deposition rate is greater than the first deposition rate. The thin film solar cell manufactured is characterized by an increased initial and stabilized efficiency while at the same time the overall deposition rate, even by depositing two different intrinsic layers (21, 22), is kept at a reasonable and economic level.

### TECHNICAL FIELD

The present invention relates to a method for manufacturing a thin film solar cell as well as to a method for manufacturing a multi-junction thin film solar cell. Further, the present invention relates to a thin film solar cell.

### BACKGROUND ART

Photovoltaic devices or solar cells are devices which convert light into electrical power. Thin film solar cells are of a particular importance for low-cost mass production since they allow for using inexpensive substrates, for example glass, and thin films of Si with the thickness in the range of 100 nm to 2 μm. One of the most used methods for the deposition of such Si layers is the plasma enhanced chemical vapour deposition (PECVD) method.

A prior art thin film solar cell in the so-called superstrate configuration is shown in FIG. 1. The solar cell includes a transparent glass as substrate 1 and a transparent conductive oxide (TCO) layer 2 deposited on the substrate 1, i.e. the front contact (TCO-FC) or electrode of the solar cell. On the TCO front contact 2 is first a positively doped Si layer 3 deposited, i.e. the p-layer, then an intrinsic absorber layer 4, i.e. the i-layer, and then a negatively doped n-layer 5. The three Si layers 3, 4, 5 form a p-i-n junction, whereby the main part of the thickness of the Si layers 3, 4, 5 is occupied by the i-layer 4, wherein the photoelectric conversion primarily occurs. On top of the Si layers 3, 4, 5 is another TCO layer 6 deposited, which is also named back-contact (TCO-BC). The TCO front and back contact layers 2, 6 can be made of zinc oxide, tin oxide or ITO. A white reflector 7 is usually applied after the back contact 6 for reflecting not yet absorbed light back into the active layers 3, 4, 5.

In the past years, a new concept of tandem cells 8 has been developed, as shown in prior art FIG. 2. The so-called tandem cell 8 allows for a better use of the solar spectra and for a reduced light induced degradation. The tandem cell 8 is based on two single junction cells 9, 10 deposited on the top of the another one. This way, the thin film solar cell 8 usually includes a first or front electrode 11 deposited on a substrate 12, one or more semiconductor thin film p-i-n junctions 13-15, 9, 16-18, 10 and a second or back electrode 19 followed by a back reflector 20, whereby the layers 11-20 are successfully stacked on each other starting with the substrate 12. Each p-i-n junction 9, 10 or thin film photovoltaic conversion unit includes an i-type layer 14, 17 sandwiched between a p-type layer 13, 16 and an n-type layer 15, 18. Substantially intrinsic in this context is understood as undoped or exhibiting essentially no resultant doping. As the photoelectric conversation primarily occurs in the i-type layers 14, 17, the intrinsic i-type layer is therefore also called absorber layer.

Depending on the crystalline fraction, the crystallinity, of the i-type layer 14, 17 solar cells 8 or photoelectric conversion devices are characterized as an amorphous, a-Si, 14, or microcrystalline, μc-Si, 17, solar cells 9, 10, independent of the kind of crystallinity of the adjacent p- and n-layers 13, 15, 16, 18. Microcrystalline layers are being understood, as common in art, as layers comprising a significant fraction of the crystalline silicon, so-called micro-crystallites, in an amorphous matrix. Stacks of p-i-n junctions 9, 10 are called tandem or triple junction photovoltaic cells 8. The combination of an amorphous and microcrystalline p-i-n junction 9, 10, as shown in prior art FIG. 2, is also called micromorph tandem cell. The a-Si cell 9 absorbs predominantly the blue part of the solar spectrum while the micro-crystalline cell 10 absorbs mostly of the red part of the solar spectra. The serial connection of the two junctions 9, 10 also helps to reduce the light induced degradation which is specific for s-Si cells 9.

In order to achieve a high stabilized efficiency of single junction a-Si solar cells as well as of tandem junction solar cells one needs to optimize the most important cell parameters that account for the cell efficiency, which are current density Jsc, open circuit voltage Voc and fill factor FF, each for themselves known from prior art and also known for the man skilled in the art on how to measure. Additionally, the light induced degradation, LID, should be reduced as much as possible. For large area mass production of solar cells additional factors such as layer and cell uniformity or deposition time are also very important factors that have to be considered.

Usually, good stabilized efficiency values can be obtained through a complex optimization process of either the initial efficiency, e.g. by improving one or more of the before discussed cell parameters, or of the LID. Such an optimization process usually comprises a trade off between initial efficiency, stabilized efficiency and deposition rate. In turn, the production of photovoltaic modules can be realized either with superior performance and long processing times or with shorter processing times and lower performance in terms of power.

### DISCLOSURE OF INVENTION

It is therefore an object of the present invention to overcome before described disadvantages of prior art, i.e. to provide a method for improving the performance of amorphous silicon single junction solar cells as well as of micromorph tandem solar cells by increasing the initial efficiency and simultaneously reducing the light induced degradation of the a-Si and micromorph tandem cells for large area mass production photovoltaic systems.

This object is achieved by the independent claims. Advantageous embodiments are detailed in the dependent claims.

Particularly, the object is achieved by a method for manufacturing a thin film solar cell, comprising the sequential steps of a) depositing a positively doped Si layer, b1) depositing a first intrinsic a-Si:H layer at a first deposition rate, b2) depositing a second intrinsic a-Si:H layer at a second deposition rate, and c) depositing a negatively doped Si layer, whereby the second deposition rate is greater than the first deposition rate.

Accordingly, the present invention is based on the idea of providing two different intrinsic absorber layers forming together the i-layer for a p-i-n-junction to result in a thin film photoelectric conversion unit, together with the positively doped Si layer and the negatively doped Si layer, when depositing the two different intrinsic layers with different deposition rates, i.e. having a second deposition rate that is greater than the first deposition rate. In turn, the thin film solar cell manufactured is characterized by an increased initial and stabilized efficiency while at the same time the overall deposition rate, even by depositing two different intrinsic layers, is kept at a reasonable and economic level. In detail, this is achieved by an intrinsic a-Si:H absorber layer for the photoelectric conversion unit of a solar cell comprising at least two intrinsic sublayers, whereby the first sublayer is of a so-called high quality a-Si:H deposited with respectively at the first deposition rate and the second sublayer is of a-Si:H deposited with respectively at a second, higher deposition rate. In such p-i-n configuration the high-quality sublayer, the first intrinsic a-Si:H layer, is arranged between the p-layer and the second sublayer, the second intrinsic a-Si:H layer. In sum, such high-quality a-Si:H layer, the first intrinsic a-Si:H layer respectively first sublayer, is achieved by controlling at least the deposition rate when depositioning the respective intrinsic layer. Preferably, the deposition of before described layers is carried out by a CVD process, most preferably within a CVD processing chamber.

The term processing in sense of the current invention comprises any chemical, physical and/or mechanical effect acting on a substrate.

The term substrate in sense of the current invention comprises a component, part or workpiece to be treated within a vacuum processing system. A substrate includes but is not limited to flat- and/or plate-shaped parts having rectangular, square or circular shapes. Preferably, the substrate is provided as an essentially, most preferably completely planar substrate having a planar surface of a size ≧1 m², such as a thin glass plate.

The term vacuum processing or vacuum treatment system in sense of the current invention comprises at least an enclosure for the substrate to be treated under pressure lower than ambient atmospheric pressure.

The term CVD, chemical vapour deposition, and its flavours, comprises in sense of the current invention, a well-known technology allowing for the deposition of layers on heated substrates. A usually liquid or gaseous precursor material, a gas, is being fed to the process system where a thermal reaction of a precursor results in the deposition of the layer. Often, DEZ, diethyl zinc, is used as precursor material for the production of TCO layers in a vacuum processing system using low pressure CVD, LPCVD.

The term TCO stands for transparent conductive oxide, i.e. TCO layers are transparent conductive layers, whereby the terms layer, coating, deposit and film are interchangeably used within this invention for a film deposited in a vacuum process, be it CVD, LPCVD, plasma enhanced CVD (PECVD) or physical vapour deposition (PVD).

The term solar cell or photovoltaic cell, PV cell comprises in sense of the current invention an electrical component, capable of transforming light, essentially sun light, directly into electrical energy by means of the photovoltaic effect.

A thin film solar cell in a generic sense includes, on a supporting substrate, at least one p-i-n junction established by a thin film deposition of semiconductor compounds, sandwiched between two electrodes or electrode layers. A p-i-n junction or thin film photoelectric conversion unit includes an intrinsic semiconductor compound layer sandwiched between a p-doped and a n-doped semiconductor compound layer. The term thin film indicates that the layers mentioned are being deposited as thin layers or films by processing like, before-mentioned PECVD, CVD, PVD or a like. Thin layers essentially mean layers with a thickness of 10 μm or less, especially less than 2 μm.

In a further preferred embodiment, the first deposition rate is ≧40% and ≦75%, preferably ≧40% and ≦60% of the second deposition rate. More preferably, the first deposition rate is 2.1 Å/sec and the second deposition rate is 3.6 Å/sec.

In a further preferred embodiment, the deposition of the layers is carried out by a CVD process using RF power having during step b1) a level of ≧30% and ≦75%, preferably ≧30% and ≦50%, compared to the level during step b2). In a further preferred embodiment, the deposition of the layers is carried out by a CVD process using hydrogen and silane as precursor gas having a hydrogen to silane flow ratio during step b1) of ≧1 and ≦1.5 compared to the hydrogen to silane flow ratio during step b2). In another preferred embodiment the deposition of the layer is carried out by a CVD process having a process pressure during step b1) of ≧30% and ≦90% compared to the process pressure during step b2). Im sum, adjusting the deposition rate and/or the RF power and/or the hydrogen to silane flow ratio as outlined before results in two different intrinsic a-Si:H layers leading to an increased initial efficiency and simultaneously reduced light induced degradation of the so manufactured thin film solar cell. Exemplary, the first intrinsic a-Si:H layer can be achieved at 0.3 mbar pressure, 180 W RF power, 1.9 Å/sec deposition rate and H₂/SiH₄=1 hydrogen to silane flow ratio,

and the second intrinsic a-Si:H layer can be achieved at 1.0 mbar pressure, 600 W RF power, 4.6 Å/sec deposition rate and H₂/SiH₄=0.25 hydrogene to silane flow ratio.

According to another preferred embodiment, the first intrinsic a-Si:H layer and the second intrinsic a-Si:H layer are deposited such that the thickness of the first intrinsic a-Si:H layer is ≧15% and ≦45%, preferably ≧15% and ≦35%, of the overall intrinsic a-Si:H layer thickness of the first intrinsic a-Si:H layer and a second intrinsic a-Si:H layer. Preferably, the thickness of the overall intrinsic a-Si:H layer of the first intrinsic a-Si:H layer and a second intrinsic a-Si:H layer is 220 nm. In a further preferred embodiment, the positively doped Si layer and/or the negatively doped Si layer comprises a-Si:H or μC—Si:H.

In a further preferred embodiment, the method comprises the sequential steps of providing a substrate, depositing a first TCO layer on the substrate, depositing the layers as described before on the first TCO layer, i.e. the positively doped Si layer, the first intrinsic a-Si:H layer, the second intrinsic a-Si:H layer and the negatively doped Si layer, on the first TCO layer, and depositing a second TCO layer on the deposited layers as described before. Such way, the photoelectric conversion device as described before is further completed with the first and the second TCO layers for electrically contacting the thin film solar cell.

The object of the invention is further addressed by a method for manufacturing a multi-junction thin film solar cell, comprising the sequential steps of providing a substrate, depositing a first TCO layer on the substrate, depositing the layers as described before on the first TCO layer forming a top solar cell, i.e. the positively doped Si layer, the first intrinsic a-Si:H layer, the second intrinsic a-Si:H layer and the negatively doped Si layer, depositing at least one another solar cell comprising in sequential order a positively doped Si layer, an intrinsic a-Si:H or μC—Si:H layer and a negatively doped Si layer on the top solar cell, and depositing a second TCO layer on the backmost another solar cell. This way, a micromorph tandem cell can be realized that is characterized by reduced top cell degradation and higher top cell current, further resulting in a significantly lower LID and higher stabilized module power, both compared to prior art micromorph tandem cells.

The object of the invention is furthermore achieved by a thin film solar cell, comprising a positively doped Si layer, a first intrinsic a-Si:H layer deposited on the positively doped Si layer, a second intrinsic a-Si:H layer deposited on the first intrinsic a-Si:H layer, and a negatively doped Si layer deposited on the second intrinsic a-Si:H layer, whereby the thickness of the first intrinsic a-Si:H layer is ≧15% and ≦45%, preferably ≧15% and ≦35%, of the overall intrinsic a-Si:H layer thickness of the first intrinsic a-Si:H layer and the second intrinsic a-Si:H layer.

In a further preferred embodiment, the first intrinsic a-Si:H layer comprises a lower H-content C_{H} incorporated in the intrinsic material than the second intrinsic a-Si:H layer, preferably the first intrinsic a-Si:H layer comprises a H-content c_{H} of ≧9% and ≦11%, most preferably of 10.1%, and the second intrinsic a-Si:H layer comprises a H-content c_{H} of ≧12% and ≦15%, most preferably of 13.7%. Preferably, the H-content c_{H} is measured via mass spectroscopy, more preferably via SIMS (secondary ion mass spectrometry).

In a further preferred embodiment, the first intrinsic a-Si:H layer comprises a lower microstructure factor R than the second intrinsic a-Si:H layer, preferably the first intrinsic a-Si:H layer comprises a microstructure factor R of ≧2% and ≦6%, most preferably of 3.9% and the second intrinsic a-Si:H layer comprises a microstructure factor R of ≧8% and ≦13%, most preferably of 10.5%.

In another preferred embodiment, the first intrinsic a-Si:H layer comprises a denser intrinsic material characterised by less defects and/or less micro-voids incorporated in the intrinsic material than the second intrinsic a-Si:H layer. Preferably, material density respectively micro-voids are measured via TEM (transmission electron microscopy).

In a further embodiment, the first intrinsic a-Si:H layer comprises a lower band gap energy than the second intrinsic a-Si:H layer, preferably the first intrinsic a-Si:H layer comprises a band gap energy of ≧1810 eV and ≦1820 eV, most preferably of 1815 eV and the second intrinsic a-Si:H layer comprises a band gap energy of ≧1825 eV and ≦1835 eV, most preferably of 1830 eV. In another preferred embodiment the overall intrinsic a-Si:H layer thickness of the first intrinsic a-Si:H layer and the second intrinsic a-Si:H layer is ≧100 nm and ≦2 μm, preferably 220 nm. Preferably, the band gap energy is indirectly measured by irradiating the material with e.g. monochromatic light and observing the long wave dependent absorption of the material.

This way, i.e. with the embodiments described before, a higher stabilized efficiency for an a-Si single junction cell as well as for tandem or multi junction cell is achieved.

### BRIEF DESCRIPTION OF DRAWINGS

These and other aspects of the invention will be apparent from and elucidated with reference to the embodiments described hereinafter.

In the drawings:

FIG. 1 shows a basic drawing of a thin film a-Si single junction solar cell in a superstrate configuration according to prior art,

FIG. 2 shows a basic drawing of a tandem junction thin film silicon photovoltaic cell according to prior art,

FIG. 3 shows a basic drawing of an a-Si single junction cell according to an embodiment of the invention,

FIG. 4 shows initial values of current density Jsc and cell efficiency of an a-Si single junction solar cell according to the invention,

FIG. 5 shows the light induced degradation of efficiency of an a-Si single junction solar cell according to another embodiment of the invention,

FIG. 6 shows the dependence of a stabilized cell efficiency as a function of a total deposition time corresponding to different solar cells manufactured according to the invention having a thickness of 220 nm,

FIG. 7 shows the relative light induced degradation of micromorph mini modules for which the top cell comprises different absorber layers,

FIG. 8 shows a table of single layer properties of the intrinsic layers of a solar cell according to a preferred embodiment of the invention,

FIG. 9 shows a table deposition rate and table deposition time for a 220 nm solar cell with two intrinsic layers according to the invention, and

FIG. 10 shows a table of process parameters and single layer properties of a high quality a-Si:H absorber layer according to the invention.

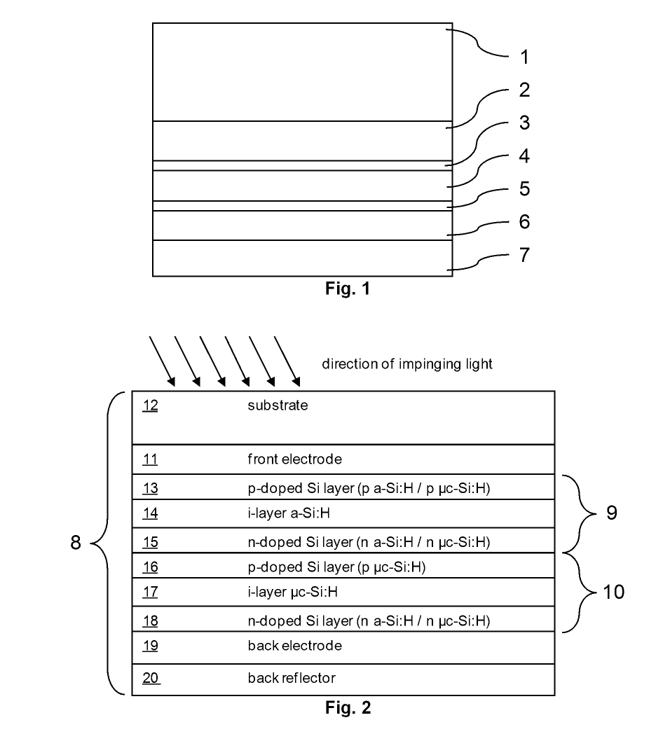

### DETAILED DESCRIPTION OF DRAWINGS

Within a solar cell 1-7, charge carriers generated in an absorber, i.e. in an intrinsic layer 4, are driven by an internal electric field to corresponding doped layers 3, 4, i.e., electrons are directed to an n-doped layer 5 while holes travel to an p-doped layer 3, as shown in prior art FIG. 1. The mobility of charge carriers is however very different for electrons and holes. The electrons have a much higher mobility than holes. Therefore, the electrons are easily collected at the n-layer 5 while difficulties may appear for the holes' collection.

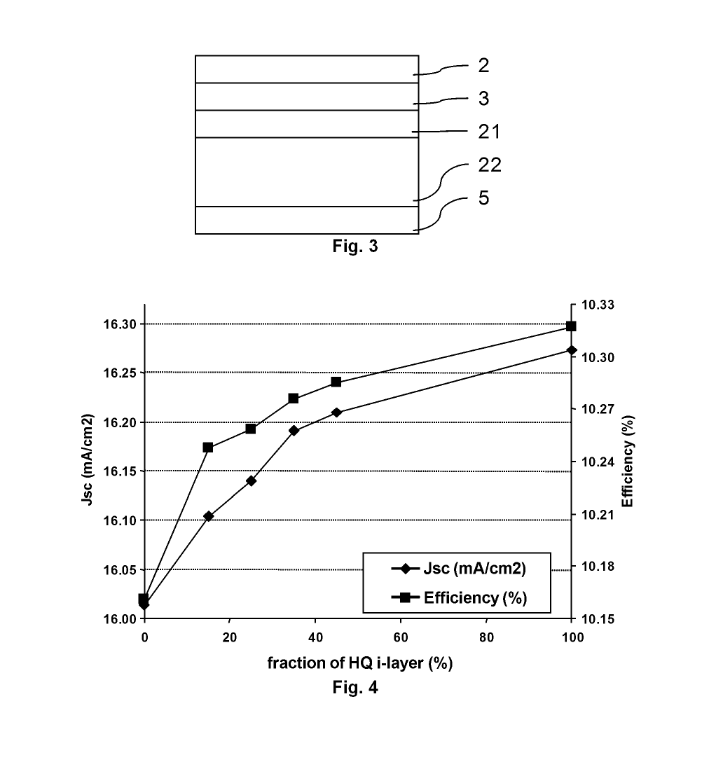

However, a so-called high quality intrinsic a-Si:H layer, i.e. a first intrinsic a-Si:H layer 21, has higher hole mobility, as shown in FIG. 3, due to the reasons outlined below. In the same time, hole conductivity for any transport mechanism in a-Si, e.g. diffusion, drift, space charge limited (SCL) current, improves with mobility. More than that, in case SCL currents are present, a piled-up positive charge close to the p/i interface plays a detrimental role for a photoelectric conversion device by screening and weakening the electric field into the i-layer 21, 22 and thus the collection efficiency. Higher hole mobility ensures lower space charge concentration and correspondingly higher collection efficiency. The absorber layer 21 with higher material quality also reduces the electron-hole recombination in the vicinity of the p-layer 3.

The hole density is significantly higher in the vicinity of the p-layer 3, compared to other regions of the i-layer 21, 22, and that is why a small fraction of the high quality absorber 21 close to the p-layer 3 is sufficient to improve the hole collection.

A modification in the cell design is employed in the following in order to improve the a-Si cell performance without a significant increase in the deposition time, as shown in FIG. 3 for an embodiment of the invention. The new cell design replaces the standard a-Si:H absorber layer 4 in the a-Si cell with a graded, or at least two-steps, a-Si:H absorber layer 21, 22, the so-called first intrinsic a-Si:H layer 21 and second intrinsic a-Si:H layer 22. For the superstrate solar cell configuration shown in prior art FIG. 1, the thin absorber layer 21 with high material quality, called in the following HQ i-layer, is deposited at the interface with the p-doped layer 3. The remaining part of the absorber layer 21, 22 consists of a production-standard a-Si:H absorber layer, in the following called Std i-layer or second intrinsic a-Si:H layer 22. Even an increase of the deposition rate compared to Prior Art or production-standard absorber layers 4 is possible.

For improving cell performance, the required thickness of the low rate HQ i-layer 21 is significantly lower than the thickness of the Std i-layer 4. Therefore, the improved cell performance in combination with processing times suitable for mass production represents the advantage of this method for industrial applications.

An example of the above described concept is given in the following: The single layer properties of the Std i-layer 4, 22 and of the HQ i-layer 21 are shown in the table of FIG. 8. The HQ i-layer 21 has lower H-content incorporated in the material and a significantly lower microstructure factor than the Std i-layer 22, i.e. the HQ i-layer 21 is a dense material characterized by less defects and micro-voids incorporated in the material. Moreover, the HQ absorber layer 21 is also characterized by lower band gap energy.

The graded a-Si:H i-layer 21, 22 employs a fraction of the HQ i-layer 21 which replaces the interface part of the Std i-layer. The table in FIG. 9 shows the deposition parameters of different graded absorbers with a total thickness of 220 nm. For instance, replacing 25% of the Std i-layer by HQ i-layer 21 results in a decrease of the deposition rate from 3.6 A/sec to 3.23 A/sec, which is equivalent to an increase of the deposition time by 11%.

Single junction a-Si solar cells with graded absorber layers 21,022 according to the table shown in FIG. 8 have been prepared. FIG. 4 shows the current density Jsc and the conversion efficiency of a-Si solar cell for which the Std i-layer 4 has been partially replaced by the HQ i-layer 21, as shown in the table in FIG. 9.

The current density increases with the increasing amount of the HQ i-layer 21 in the graded i-layer 21, 22. Moreover, the increase of current density is stronger for the graded i-layers 21, 22 with an amount of HQ i-layer 21 up to 35% than for the graded i-layers 21, 22 with a higher amount of HQ i-layer 21. This is due to the fact that the charge carriers generated in the absorber layer are more efficiently collected when using the HQ i-layer 21 at the interface with the p-doped layer 3 due to a better hole mobility and collection. Since the open circuit voltage and the fill factor of the solar cells with the different graded i-layers 21, 22 do not change significantly with the fraction of the HQ i-layer 21, the cell efficiency for the different absorber layers follows a similar trend as the one of the current density. This is also shown in FIG. 4. The cell efficiency increases stronger for small fractions of HQ i-layer 21 than for higher HQ i-layer 21 fractions. This non-linear increase of the cell efficiency with the fraction of HQ i-layer 21 reflects the potential of this method for being used in industrial processes for PV applications. The term “fraction” as used herein and shown in FIG. 4 is being understood as material fraction of the total i-layer 21, 22.

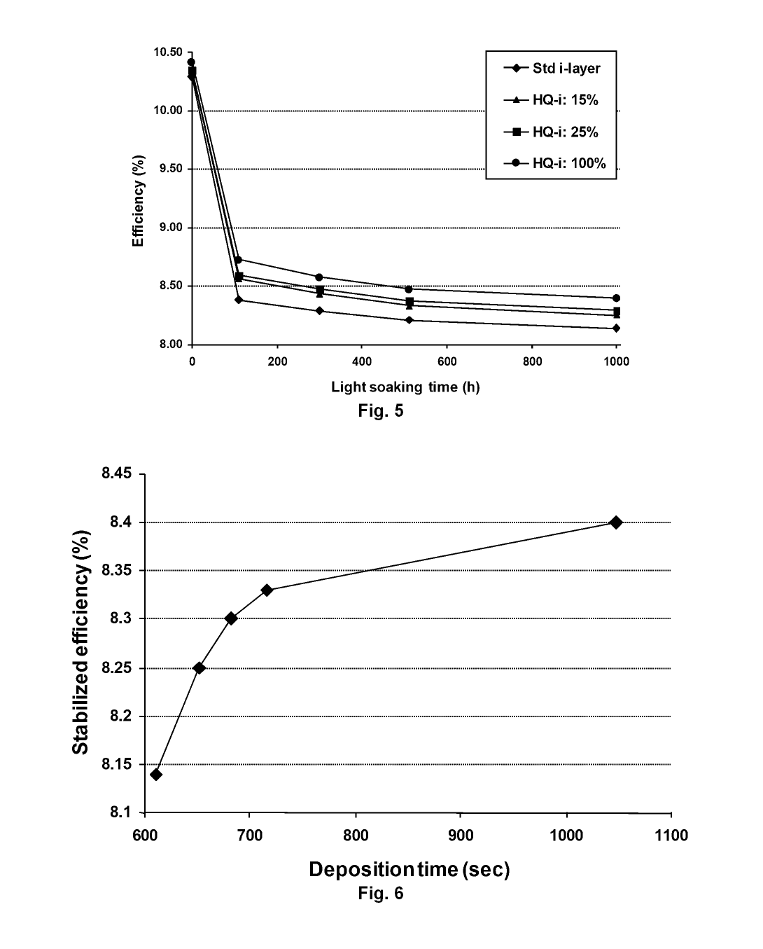

The improved performance of the solar cells with the graded i-layers 21, 22 is even more evident after light induced degradation. FIG. 5 shows the decrease of efficiency of the solar cells with different absorbers due to light induced degradation. After 1000 hours of light soaking, the cells with graded i-layer 21, 22 have higher stabilized efficiency and lower relative degradation than the cells with the Std i-layer 4. It is worth mentioning that the cells which contain 25% HQ i-layer 21 have a stabilized efficiency which is closer to that of the cells with 100% HQ i-layer 21 that to that of the cells with 100% Std i-layer 4.

For the industrial mass production of solar modules the total deposition time of the absorber layer is a very important parameter with respect to the production throughput. FIG. 6 shows the stabilized cell efficiency as a function of the total deposition time for different graded a-Si:H i-layers 21, 22 with a thickness of 220 nm. The relevance of the graded a-Si:H absorbers 21, 22 for industrial PV processes can easily be understood: a small fraction of 15-35% HQ i-layer 21 at the p/i interface contributes to an increase in the stabilized cell efficiency which is closer to that of a solar cell with 100% HQ i-layer 21. The deposition time of the graded i-layer 21, 22 with 15-35% HQ i-layer 21 is however significantly lower than the deposition time required for a solar cell with 100% HQ i-layer 21. For industrial applications, the ratio of the HQ i-layer 21 is chosen in accordance to the required cell performance and deposition time.

The strength of the improved performance due to graded a-Si:H i-layer 21, 22 concept might be dependent on the difference in the quality of the two absorber layers 21, 22 that constitute the graded layer 21, 22: the stronger the difference in the material quality of the two layers 21, 22 the stronger is the effect of the graded a-Si:H i-layer 21, 22.

The graded a-Si:H i-layer 21, 22 has also beneficial effects for the production of micromorph tandem modules. The lower light induced degradation and simultaneously higher current density for the top cell 9 are the key elements needed for a lower light induced degradation of micromorph modules. In FIG. 4 it was shown that the higher initial efficiency of the a-Si single junction cells with graded absorber layers 21, 22 is mainly due to the higher current density. Moreover, from FIG. 5 one can observe that the cells with the graded a-Si:H i-layers 21, 22 exhibit a higher stabilized efficiency and therefore a lower light induced degradation as compared to the cells that contain the standard a-Si:H absorber 4.

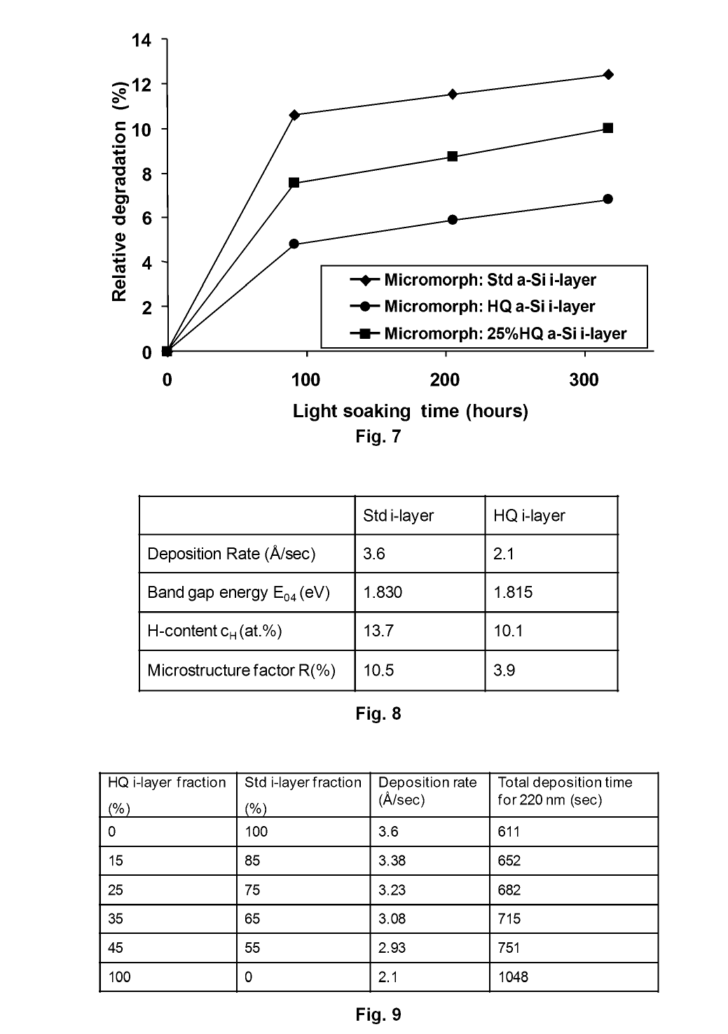

Hence, these two effects provide a significant improvement in the relative degradation of bottom-limited micromorph tandem modules. FIG. 7 shows that indeed micromorph modules which contain a graded a-Si:H absorber layer 21, 22 in the top cell 9 exhibit a significantly lower light induced degradation than the micromorph modules with the Std a-Si:H i-layer 4, 14 in the top cell 9. Similar with the case of a-Si single junction cells, the relative degradation values of the micromorph modules comprising the graded a-Si:H i-layers 21, 22 in the top cell 9 are in between those of the modules with the Std i-layer 4, 14 and HQ i-layer 21 in the top cell 9. Hence, a significantly improved light induced degradation of micromorph modules is achieved when using a graded a-Si:H i-layers 21, 22 at the only expense of a slightly higher deposition time for the a-Si:H absorber layer 4, 14. For the whole tandem cell, the relative increase in time due to use of graded a-Si:H i-layers 21, 22 in top cell 9 is significantly lower than the relative increase in time for the a-Si single junction.

The known PECVD process for the deposition of standard hydrogenated amorphous Si (a-Si:H) absorber layers 4 needs to be tuned in order to obtain a better material quality and higher current density. The common method of increasing the current density of an a-Si cell is to reduce the band gap energy of the absorber layer 4 by reducing the H-dilution of the SiH₄ plasma. However, at least two negative effects can arise when applying this method: the Voc decreases and the LID increases. Contrary to the common method, a combination of reduced process pressure and RF power density is employed here in order to simultaneously increase the current density and reduce the light induced degradation. The deposition rate is the trade off factor of this method.

A state of the art a-Si:H absorber layer 4 for large area mass production a-Si and tandem solar cells is deposited by diluting the SiH₄ gas by H₂ in a ratio of 1:1. Typical deposition rates for such absorber layers 4 are about 3.2-3.6 Å/sec.

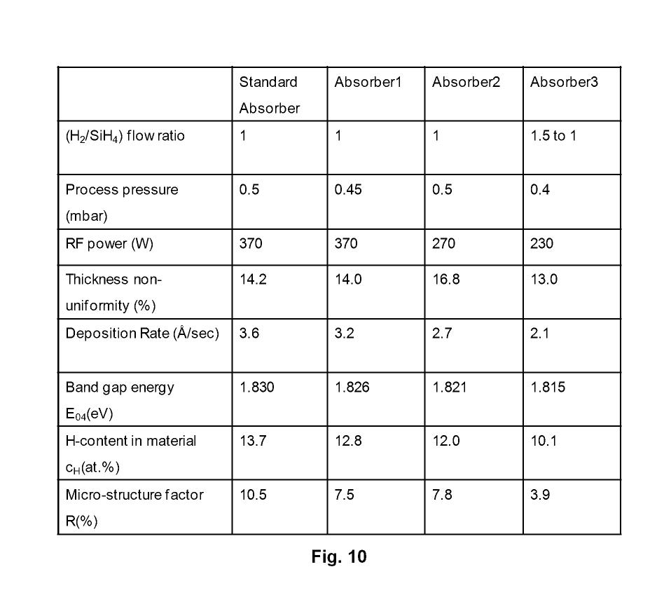

By reducing either the process pressure, e.g. down to 0.3 mbar, or the RF power density one can improve the material quality and slightly reduce the band gap energy of the a-Si:H absorber layer 4, resulting in the first s-Si:H intrinsic layer 21 i.e. the HQ i-layer 21. This is shown in the table in FIG. 10 where the single layer properties are presented for two absorber layers for which either the process pressure, column absorber1, or the RF power density, column absorber2, was reduced. The material quality factor, or microstructure factor R, derived from FTIR measurements, which is a measure of the micro-voids in the material is reduced for the absorber1 and absorber2, indicating a dense material with less Si—H₂ and Si—H₃ bonds.

The improved material quality and the reduced H-content incorporated in the absorber1 and absorber2 layers with respect to the standard a-Si:H absorber layer 4, 22 are two factors which are thought to contribute to a lower light induced degradation. The deposition rate of the absorber1 and absorber2 layers is slightly reduced. The layer non-uniformity over large areas, e.g. 1.4 m², of the absorber2 layer is slightly higher than that of the standard absorber layer 4.

Significant improvement of material quality and reduction of band gap energy is given by the combination of reduced process pressure and RF power in the a-Si:H PECVD process. This is shown in the table of FIG. 10 for the absorber3 layer, i.e. the first intrinsic layer 21. The material parameters of the absorber3 layer are significantly improved with respect to those of the standard absorber 22 and the absorber1 and absorber2: much better microstructure factor, i.e. significantly less micro-voids and denser material as well as significantly lower H-content incorporated in the layer. The band gap energy E₀₄ is also slightly reduced for the absorber3 layer. The deposition rate of the absorber3 layer is lower, but still above 2 Å/sec. Such a-Si:H absorber layers with excellent material quality at lower deposition rate are very advantageous for large area mass production a-Si single junction and a-Si based tandem solar cells for which a lower light induced degradation and higher stabilized power are required.

Single junction a-Si solar cells with the above described absorber layers have been prepared on LPCVD ZnO FC. For all cells the thickness of the absorber layer was 265 nm and beside the different absorber layers the cell structure was the same for all cells.

The current density of the cells comprising the new absorber layers 21 is higher than that of the cells comprising the standard a-Si:H absorber layer 4, 22. The most significant increase in current density corresponds to the absorber3 layer for which the combination of reduced process pressure and RF power density was applied. The higher current density of the solar cells including the new absorber layers is due to a slightly lower band gap energy and improved material quality, as shown in the table of FIG. 10.

The initial and stabilized performance of the solar cells with the different absorber layers strongly correlate with the single layer properties of the different absorber layers shown in the table of FIG. 10. For instance, the highest current density, highest stabilized efficiency and lowest relative degradation for the absorber3 layer are the consequence of the best material quality of this absorber layer with respect to the other absorber layers.

The high quality a-Si:H absorber layer 21 was primarily optimized for being used in top cells 9 of micromorph tandem cells. However, they might be used in any single, double or triple junction cell concept when more current density and lower light induced degradation are needed.

While the invention has been illustrated and described in detail in the drawings and foregoing description, such illustration and description are to be considered illustrative or exemplary and not restrictive; the invention is not limited to the disclosed embodiments. Other variations to be disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting scope.

### REFERENCE SIGNS LIST

1 substrate
2 front electrode
3 p-layer
4 i-layer
5 n-layer
6 back electrode
7 reflector
8 tandem junction thin film photovoltaic cell
9 top cell
10 bottom cell
11 front electrode
12 substrate
13 p-layer
14 i-layer
15 n-layer
16 p-layer
17 i-layer
18 n-layer
19 back electrode
20 reflector
21 first intrinsic layer
22 second intrinsic layer

1. Method for manufacturing a thin film solar cell, comprising the sequential steps of
a) depositing a positively doped Si layer (3),
b1) depositing a first intrinsic a-Si:H layer (21) at a first deposition rate,
b2) depositing a second intrinsic a-Si:H layer (22) at a second deposition rate, and
c) depositing a negatively doped Si layer (5), whereby
the second deposition rate is greater than the first deposition rate.

2. Method according to the previous claim, whereby the first deposition rate is ≧40% and ≦75%, preferably ≧40% and ≦60%, of the second deposition rate, more preferably the first deposition rate is 2.1 Å/sec and the second deposition rate is 3.6 Å/sec.

3. Method according to any of the previous claims, whereby the deposition of the layers (3, 21, 22, 4) is carried out by a CVD process using RF power having during step b1) a level of ≧30% and ≦75%, preferably ≧30% and ≦50%, compared to the level during step b2).

4. Method according to any of the previous claims, whereby the deposition of the layers (3, 21, 22, 4) is carried out by a CVD process using hydrogen and silane as precursor gas having a hydrogen to silane flow ratio during step b1) of ≧1 and ≦1.5 compared to the hydrogen to silane flow ratio during step b2).

5. Method according to any of the previous claims, whereby the deposition of the layers (3, 21, 22, 4) is carried out by a CVD process having a process pressure during step b1) of ≧30% and ≦90% compared to the process pressure during step b2).

6. Method according to any of the previous claims, whereby the first intrinsic a-Si:H layer (21) and the second intrinsic a-Si:H layer (22) are deposited such that the thickness of the first intrinsic a-Si:H layer (21) is ≧15% and ≦45%, preferably ≧15% and ≦35%, of the overall intrinsic a-Si:H layer (21, 22) thickness of the first intrinsic a-Si:H layer (21) and the second intrinsic a-Si:H layer (22).

7. Method according to any of the previous claims, whereby the positively doped Si layer (3) and/or the negatively doped Si layer (5) comprises a-Si:H or μc-Si:H.

8. Method according to any of the previous claims, comprising the sequential steps of
providing a substrate (1),
depositing a first TCO layer (2) on the substrate (1),
depositing the layers (3, 21, 22, 4) according to any of the previous claims on the first TCO layer (2), and
depositing a second TCO layer (6) on the deposited layers (3, 21, 22, 4) according to any of the previous claims.

9. Method for manufacturing a multi-junction thin film solar cell, comprising the sequential steps of
providing a substrate (1, 12),
depositing a first TCO layer (2, 22) on the substrate (1, 12),
depositing the layers (3, 21, 22, 4) according to any of the previous claims 1 to 7 on the first TCO layer (2, 22) forming a top solar cell (9),
depositing at least one another solar cell (10) comprising in sequential order a positively doped Si layer (16), an intrinsic a-Si:H or μc-Si:H layer (17) and a negatively doped Si layer (18) on the top solar cell (9), and
depositing a second TCO layer (6, 19) on the backmost another solar cell (10).

10. Thin film solar cell, comprising
a positively doped Si layer (3),
a first intrinsic a-Si:H layer (21) deposited on the positively doped Si layer (3),
a second intrinsic a-Si:H layer (22) deposited on the first intrinsic a-Si:H layer (21), and
a negatively doped Si layer (5) deposited on the second intrinsic a-Si:H layer (22), whereby
the thickness of the first intrinsic a-Si:H layer (21) is ≧15% and ≦45%, preferably ≧15% and ≦35%, of the overall intrinsic a-Si:H layer (21, 22) thickness of the first intrinsic a-Si:H layer (21) and the second intrinsic a-Si:H layer (22).

11. Thin film solar cell according to claim 10, whereby the first intrinsic a-Si:H layer (21) comprises a lower H-content c_{H} incorporated in the intrinsic material than the second intrinsic a-Si:H layer (22), preferably the first intrinsic a-Si:H layer (21) comprises a H-content c_{H} of ≧9% and ≦11%, most preferably of 10.1%, and the second intrinsic a-Si:H layer (22) comprises a H-content c_{H} of ≧12% and ≦15%, most preferably of 13.7%.

12. Thin film solar cell according to any of the previous claims 10 or 11, whereby the first intrinsic a-Si:H layer (21) comprises a lower microstructure factor R than the second intrinsic a-Si:H layer (22), preferably the first intrinsic a-Si:H layer (21) comprises a microstructure factor R of ≧2% and ≦6%, most preferably of 3.9% and the second intrinsic a-Si:H layer (22) comprises a microstructure factor R of ≧8% and ≦13%, most preferably of 10.5%.

13. Thin film solar cell according to any of the previous claims 10 to 12, whereby the first intrinsic a-Si:H layer (21) comprises a denser intrinsic material characterised by less defects and/or less micro-voids incorporated in the intrinsic material than the second intrinsic a-Si:H layer (22).

14. Thin film solar cell according to any of the previous claims 10 to 13, whereby the first intrinsic a-Si:H layer (21) comprises a lower band gap energy than the second intrinsic a-Si:H layer (22), preferably the first intrinsic a-Si:H layer (21) comprises a band gap energy of ≧1810 eV and ≦1820 eV, most preferably of 1815 eV and the second intrinsic a-Si:H layer (22) comprises a band gap energy of ≧1825 eV and ≦1835 eV, most preferably of 1830 eV.

15. Thin film solar cell according to any of the previous claims 10 to 14, whereby the overall intrinsic a-Si:H layer (21, 22) thickness of the first intrinsic a-Si:H layer (21) and the second intrinsic a-Si:H layer (22) is ≧100 nm and ≦2 μm, preferably 220 nm.
